(19) United States
(12) Patent Application Publication
(10) Pub. No.: US 2006/0175045 A1
(43) Pub. Date: Aug. 10, 2006

(54) Heat dissipation device

(76) Inventor: Yin-Hung Chen, Taipei (TW)

Correspondence Address: Yi-Wen Tseng, 4331 Stevens Battle Lane, Fairfax, VA, 22033, US

(21) Appl. No.: 10/803,924

(22) Filed: Mar. 19, 2004

(51) Int. Cl. H05K 7/20

(52) U.S. Cl. 165/104.33; 165/80.3; 361/700

(57) ABSTRACT

An integrated heat dissipation device includes a heat sink portion having a base with a plurality of posts formed thereon, a fin portion with a plurality of stacked fins, individually formed over the heat sink portion, and at least two L-shaped heat pipes installed in the heat sink portion and extended to the fin portion. The heat pipes are staggeredly arranged to have a well-proportioned scatteration in the fin portion such that the heat conducted by the heat pipes can be uniformly distributed to the fins for dissipation. As such, a heat dissipation device with enhanced heat-dissipating efficiency is obtained.

### BACKGROUND OF THE INVENTION

The present invention relates to a heat dissipation device, and more particular, to a computer heat dissipation device which has enhanced heat-dissipating efficiency.

FIG. 1 shows a conventional heat dissipation device 10a applied to central processing units (CPUs) of a computer. The heat dissipation device 10a includes an aluminum extruded heat sink 1a, a plurality of fins 11 a integrated on the heat sink 1a, and a fan attached to the fins 11a. To enhance the heat dissipating performance of the heat dissipation device 10a, a thermal conductive block 12a is embedded in the bottom of the heat sink 1a. The thermal conductive block 12a is fabricated from good thermal conductive material such as copper. A receiving slot 13a is formed on the bottom of the heat sink 1a, such that the thermal conductive block 12a can be accommodated in the receiving slot 13a. Thereby, the heat dissipation device 10a can be mounted on a central processing unit 21a of a printed circuit board (PCB) 8. Via the thermal conductive block 12a, heat generated by the CPU 21a is conducted to the fins 11a. Further via the fan, the heat can be effectively dissipated.

However, though the above heat dissipation device 10a incorporates the thermal conductive block 12a to conduct the heat, heat will be accumulated in the heat sink la because the thermal conductive block 12a is located at the bottom of the heat dissipation device 10a and the top portions of the fins 11a are spaced from each other by a relative large distance. Therefore, currently it is the aim to provide a heat dissipation device with enhanced heat-dissipating efficiency for the heat dissipation requirement of the next CPU generation with faster operation speed.

To resolve the problems caused by the conventional heat dissipation device as described above, the Applicant, with many years of experience in this field, has developed an improved heat dissipation device as described as follows.

### BRIEF SUMMARY OF THE INVENTION

The present invention provides an integrated heat dissipation device having separately formed heat sink portion and fin portion, which incorporates a plurality of heat pipes to enhance heat-dissipating efficiency.

In one aspect, the heat dissipation device provided by the present invention includes a heat sink portion having a base with a plurality of posts formed thereon, a fin portion with a plurality of stacked fins, individually formed over the heat sink portion, and at least two L-shaped heat pipes installed in the heat sink portion and extended to the fin portion. As such, a heat dissipation device with enhanced heat-dissipating efficiency is obtained.

In another aspect, the heat pipes are staggeredly arranged to have a well-proportioned scatteration in the fin portion such that the heat conducted by the heat pipes can be uniformly distributed to the fins for dissipation.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

These, as well as other features of the present invention, will become apparent upon reference to the drawings wherein:

FIG. 1 shows an exploded view of a conventional heat dissipation device;

FIG. 2 shows an exploded view of a heat dissipation device provided by the present invention;

FIG. 3 shows a perspective view of the heat dissipation device as shown in FIG. 2;

FIG. 4 shows a cross-sectional view of the heat dissipation device as shown in FIG. 3;

FIG. 5 shows another cross-sectional view of the heat dissipation device as shown in FIG. 3;

FIG. 6 shows an exploded view of an assembly of the heat dissipation device as shown in FIG. 3 with a fan and a shield; and

FIG. 7 shows a perspective view of the assembly as shown in FIG. 6.

### DETAILED DESCRIPTION OF THE INVENTION

Reference will now be made in detail to the preferred embodiments of the present invention, examples of which are illustrated in the accompanying drawings. Wherever possible, the same reference numbers are used in the drawings and the description to refer to the same or like parts.

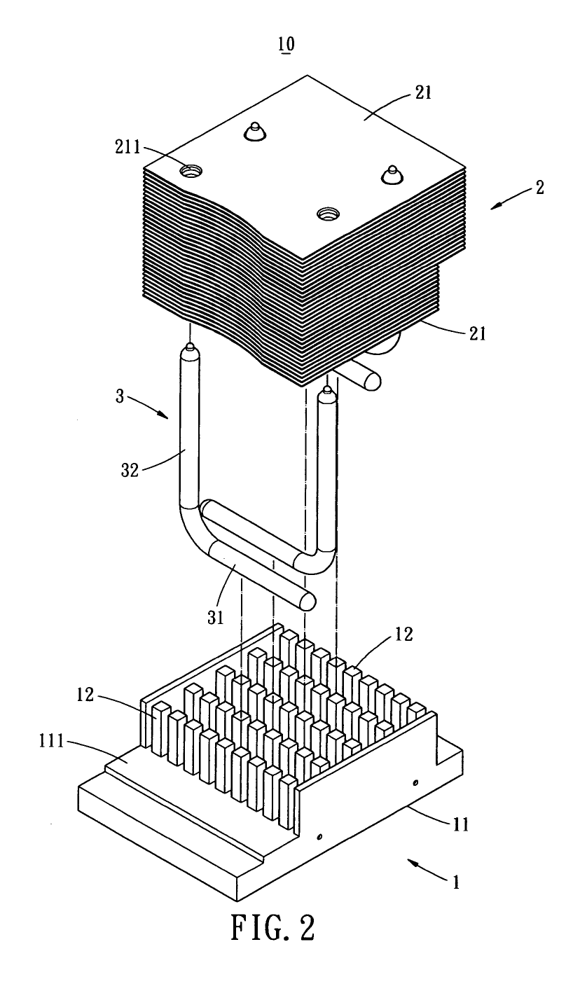

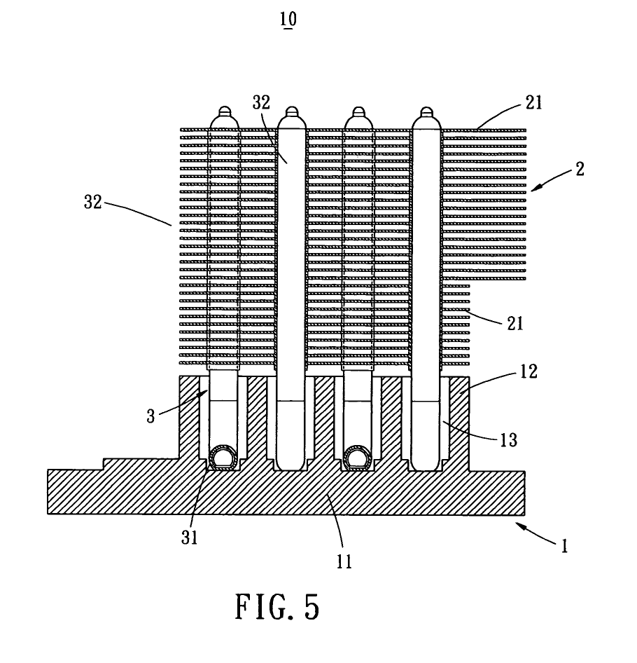

FIG. 2 depicts an exploded view of a heat dissipation device provided by the present invention. As shown, the heat dissipation device 10 is applied to a central processing unit (CPU) and includes a heat sink portion 1. The heat sink portion 1 includes a base 11 to contact with the CPU and a thermal conductive unit 12 with a plurality of posts formed thereon. The posts are aligned in multiple rows with a passage 13 (as shown in FIG. 5) formed between two rows. Both the base 11 and the thermal conductive unit 12 are preferably made of aluminum. Furthermore, one side of the base 11 has a mounting area 111 adjacent to the thermal conductive unit 12.

The heat dissipation device 10 further includes a fin portion 2 formed over the heat sink portion 1. The fin portion 2 includes a plurality of planar fins 21 stacked with each other along a vertical direction. Preferably, the fins 21 are made of aluminum. Moreover, the heat dissipation device 10 includes at least two L-shaped heat pipes 3. Each of the heat pipes 3 contained working fluid includes a horizontal extension 31 serving as a heat absorption portion, and a vertical extension 32 serving as a heat-dissipating portion. Each of the vertical extensions 32 of the heat pipes 3 is passed through a hole 211 correspondingly formed in each fin 21 such that the heat pipes 3 are staggeredly arranged inside the fin portion 2.

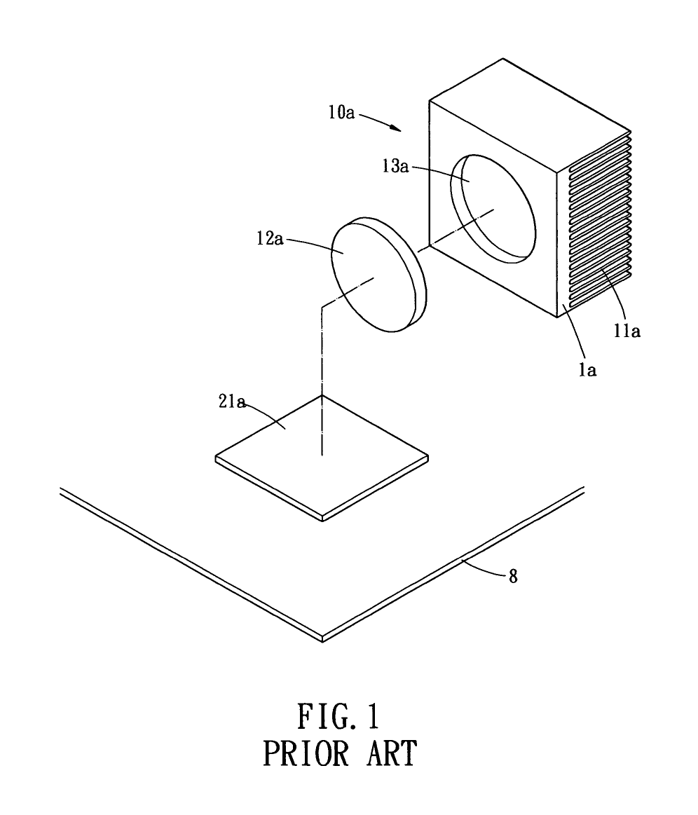

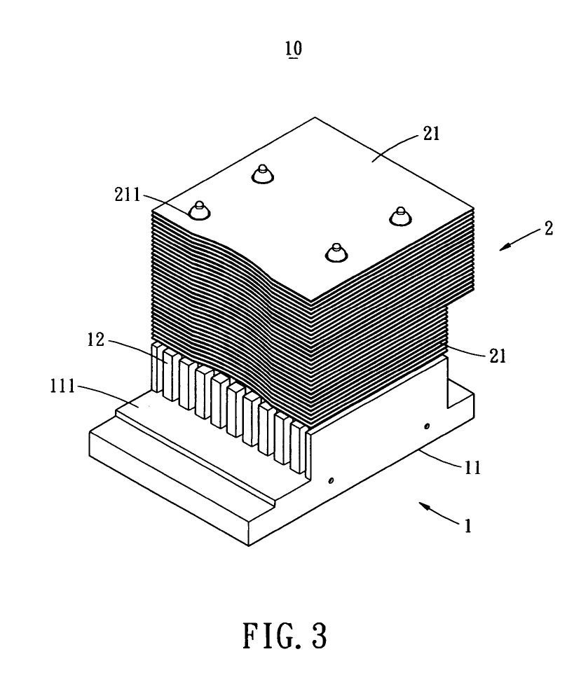

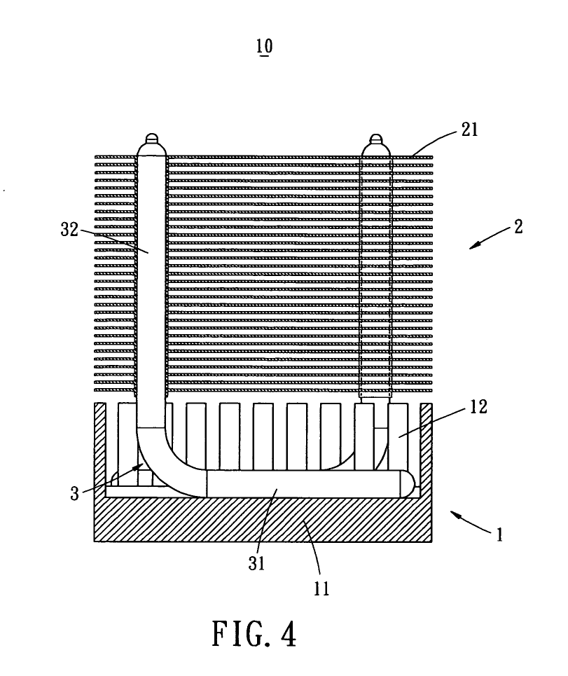

As shown in FIGS. 3 and 4, in assembly of the heat dissipation device 10 of FIG. 1, each of the horizontal extensions 31 of the heat pipes 3 is disposed in the passage 13 between two rows of the post-type thermal conductive unit 12. Thereafter, the fins 21 of the fin portion 2 are installed on the thermal conductive unit 12 to have the vertical extensions 32 of the heat pipes 3 mounted therein.

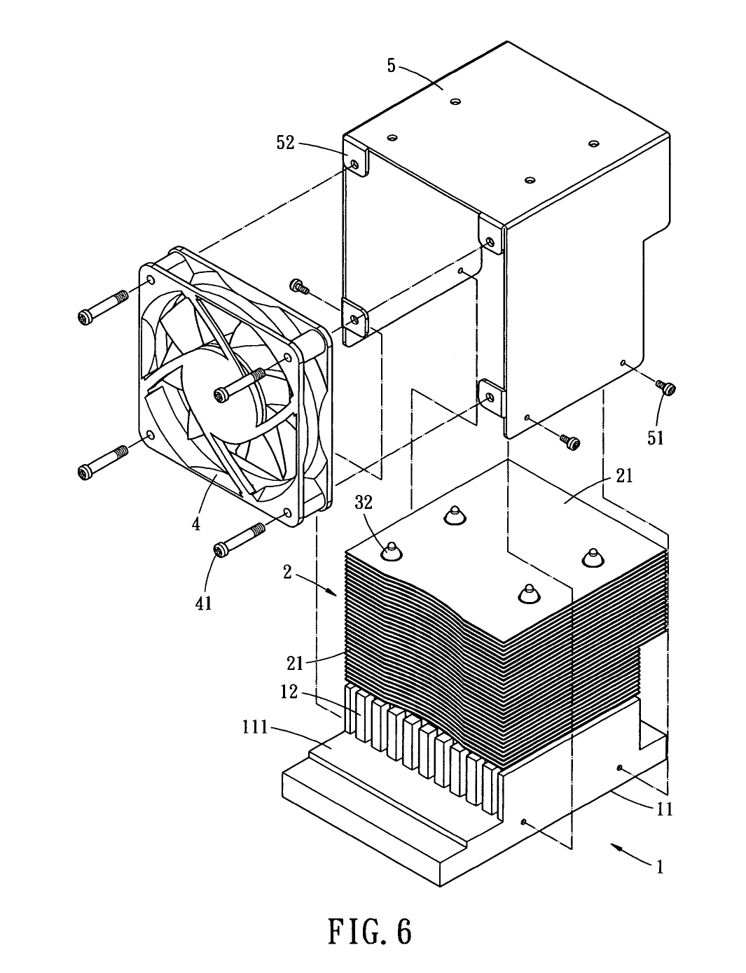

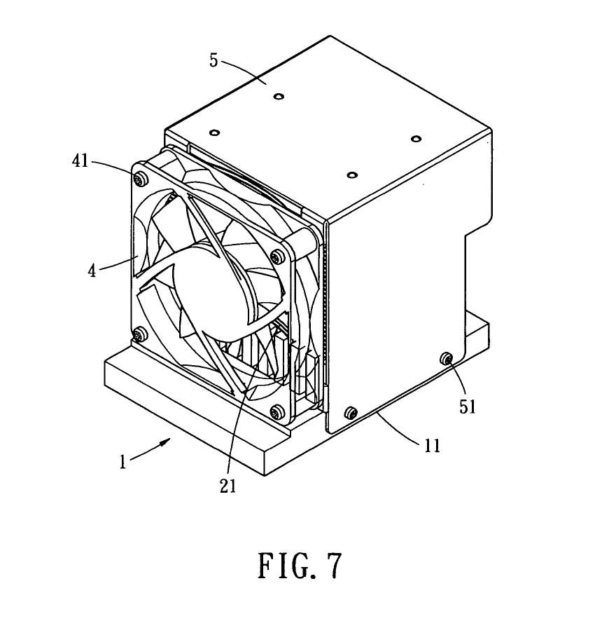

As shown in FIGS. 6 and 7, the heat dissipation device 10 may further includes a fan 4 and a shield 5. The shield 5 which is made of metal encloses two sides of the heat sink portion 1 and the fin portion 2. A screw device 51 is used to fasten the shield 5 on the base 11 of the sink portion 1. Furthermore, the fan 4 is installed on the mounting area 111 which is abutted to one open side of the shield 5. A bolt device 41 is used to fasten the fan 4 to the protrusions 52 of the shield 5. Therefore, the fan 4 is fixed on the base 11 of the heat sink portion 1.

When the dissipation device 10 of the present invention is installed on the CPU, the base 11 of the heat sink portion 1 is attached on the surface of the CPU. Meanwhile, the heat sink portion 1 conducts the heat generated by the CPU or other electronic components during the operation. Therefore, heat can be in one way dissipated by the fan 4 to circulate cool air, and one the other hand, by the heat pipes 3 to deliver heat to the fins 21.

As such, in the combination of the heat sink portion 1, the fin portion 2 and the heat pipes 3, the heat generated by CPU and other components can be dissipated rapidly so that the heat dissipation device 10 of the present invention can provide enhanced heat-dissipating efficiency.

Accordingly, the present invention uses the concept of driven array antenna to generate half-wave antenna members spaced from each other by slots to increase bandwidth of frequency domain. The simple structure successfully establishes an omni-directional radiation field with improved bandwidth. This disclosure provides exemplary embodiments of the present invention. The scope of this disclosure is not limited by these exemplary embodiments. Numerous variations, whether explicitly provided for by the specification or implied by the specification, such as variations in shape, structure, dimension, type of material or manufacturing process may be implemented by one of skill in the art in view of this disclosure.

1. An heat dissipation device, comprising:
a heat sink portion, including a base and a thermal conductive unit with a plurality rows of vertical posts formed thereon;
a fin portion mounted over the heat sink portion, including a plurality of planar fins stacked with each other along a vertical direction; and
at least two heat pipes, each having a horizontal extension disposed on the base between rows of vertical posts and a vertical extension passed through the fin portion to obtain a staggered arrangement therein.

2. The device of claim 1, further comprising a shield partially enclosing the heat sink portion and the fin portion.

3. The device of claim 2, wherein the shield is made of metal.

4. The device of claim 2, wherein the shield is fastened on the base by a screw device.

5. The device of claim 1, wherein the base further includes a mounting area formed on one side adjacent to the thermal conductive unit.

6. The device of claim 5, further comprising a fan installed on the mounting area.

7. The device of claim 6, further comprising a shield partially enclosing the heat sink portion and the fin portion.

8. The device of claim 7, wherein the shield is made of metal.

9. The device of claim 7, wherein the shield is fastened on the base by a screw device.

10. The device of claim 1, wherein the heat pipe is L-shaped.

11. The device of claim 1, further comprising a fan installed adjacent the thermal conductive unit.

12. The device of claim 11, further comprising a shield partially enclosing the heat sink portion and the fin portion.

13. The device of claim 12, wherein the shield is made of metal.

14. The device of claim 12, wherein the shield is fastened on the base by a screw device.
